(19) United States
(12) Patent Application Publication
(10) Pub. No.: US 2008/0251864 A1
(43) Pub. Date: Oct. 16, 2008

(54) STACKED POLY STRUCTURE TO REDUCE THE POLY PARTICLE COUNT IN ADVANCED CMOS TECHNOLOGY

(76) Inventors: Yuanning Chen, Plano, TX (US); Stephanie W. Butler, Richardson, TX (US); Ajith Varghese, McKinney, TX (US); Narendra Singh Mehta, Dallas, TX (US)

Correspondence Address: TEXAS INSTRUMENTS INCORPORATED, P O BOX 655474, M/S 3999, DALLAS, TX, 75265, US

(21) Appl. No.: 11/733,987

(22) Filed: Apr. 11, 2007

(51) Int. Cl. H01L 29/78; H01L 21/336

(52) U.S. Cl. 257/412; 438/303; 257/E29.255; 257/E21.409

(57) ABSTRACT

A method for implementing a stacked gate, comprising forming a gate dielectric on a semiconductor body, forming a first layer of gate electrode material on the gate dielectric, forming a second layer of gate electrode material on the first layer of gate electrode material, wherein the grain size distribution of the first layer of gate electrode material is different than the grain size distribution of the second layer of gate electrode material, implanting the first and second gate electrode materials, patterning the first and the second gate electrodes and the gate dielectric, and forming source and drain regions.

### FIELD

The disclosure herein relates generally to semiconductor processing, and more particularly to implementing a stacked poly structure to reduce the poly particle count and/or increase dopant activation in polysilicon and/or decrease line edge roughness and variability.

### BACKGROUND

Several trends presently exist in the semiconductor and electronics industry. Devices are continually being made smaller, faster and requiring less power. One reason for these trends is that more personal devices are being fabricated that are relatively small and portable, thereby relying on a battery as their primary supply. For example, cellular phones, personal computing devices, and personal sound systems are in great demand in the consumer market. In addition to being smaller and more portable, personal devices also require increased memory and more computational power and speed. In light of these trends, there is an ever increasing demand in the industry for smaller and faster transistors used to provide the core functionality of the integrated circuits used in these devices.

Accordingly, in the semiconductor industry there is a continuing trend toward manufacturing integrated circuits (ICs) with higher densities. To achieve high densities, there has been and continues to be efforts toward scaling down dimensions (e.g., at smaller technology nodes) on semiconductor wafers, that are generally produced from bulk silicon. In order to accomplish such high densities, smaller feature sizes, smaller separations between features, and more precise feature shapes are required in integrated circuits (ICs) fabricated on small rectangular portions of the wafer, commonly known as die. This may include the width and spacing of interconnecting lines, spacing and diameter of contact holes, as well as the surface geometry of various other features (e.g., corners and edges).

It can be appreciated that significant resources go into scaling down device dimensions and increasing packing densities. For example, significant man hours may be required to design such scaled down devices, equipment necessary to produce such devices may be expensive and/or processes related to producing such devices may have to be very tightly controlled and/or be operated under very specific conditions, etc. Accordingly, it can be appreciated that there can be significant costs associated with exercising quality control over semiconductor fabrication, including, among other things, costs associated with discarding defective units, and thus wasting raw materials and/or man hours, as well as other resources, for example. Additionally, since the units are more tightly packed on the wafer, more units are lost when some or all of a wafer is defective and thus has to be discarded due to poly particles and/or poly contamination.

Accordingly, techniques that mitigate yield loss due to poly related defects (e.g., a reduction in the number of unacceptable or unusable units), among other things, is desirable.

### SUMMARY

The following presents a summary to provide a basic understanding of one or more aspects of the disclosure herein. This summary is not an extensive overview. It is intended neither to identify key or critical elements nor to delineate the scope of the disclosure herein. Rather, its primary purpose is merely to present one or more aspects in a simplified form as a prelude to a more detailed description that is presented later.

A stacked poly structure can be implemented in forming a transistor. The scheme, among other things, allows poly gates of the transistor to be coated with poly having a finer crystalline structure, or rather having a lower opportunity to generate poly particles/contamination. The scheme also allows transistors to be made with reduced poly particle related defects and yet having similar electrical characteristics to current transistors. This mitigates yield loss by facilitating more predictable or otherwise desirable transistor behavior.

It is another aspect of the present invention to provide a method for implementing a stacked gate, comprising forming a gate dielectric on a semiconductor body, forming a first layer of gate electrode material on the gate dielectric, forming a second layer of gate electrode material on the first layer of gate electrode material, wherein the grain size of the first layer of gate electrode material is different than the grain size of the second layer of gate electrode material, implanting the first and second gate electrode materials, patterning the first and the second gate electrodes and the gate dielectric, and forming source and drain regions.

It is yet another aspect of the present invention to fabricate a semiconductor device formed by the process of, forming a semiconductor body, forming a gate dielectric on the semiconductor body, depositing a first gate electrode with a first grain size on the gate dielectric, and depositing a second gate electrode with a second grain size on the first gate electrode.

To the accomplishment of the foregoing and related ends, the following description and annexed drawings set forth certain illustrative aspects. Other aspects, advantages and/or features may, however, become apparent from the following detailed description when considered in conjunction with the annexed drawings.

### BRIEF DESCRIPTION OF THE DRAWINGS

FIG. 1 is a flow diagram illustrating an example methodology for implementing a stacked poly gate structure, according to an aspect of the present invention;

FIGS. 2-9 are cross-sectional views of an example semiconductor substrate whereon a stacked poly gate structure scheme is implemented in forming a transistor; according to yet other aspects of the present invention vs. a conventional method;

FIG. 10 is a graph of polysilicon particle generation utilizing a method, in accordance with an aspect of the present invention; and

FIG. 11 is a graph of particles measured with a single polysilicon gate vs. a stacked polysilicon gate, according to yet another aspect of the present invention.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one skilled in the art, that one or more aspects described herein may be practiced with a lesser degree of these specific details. In other instances, known structures and devices are shown in block diagram form to further facilitate understanding.

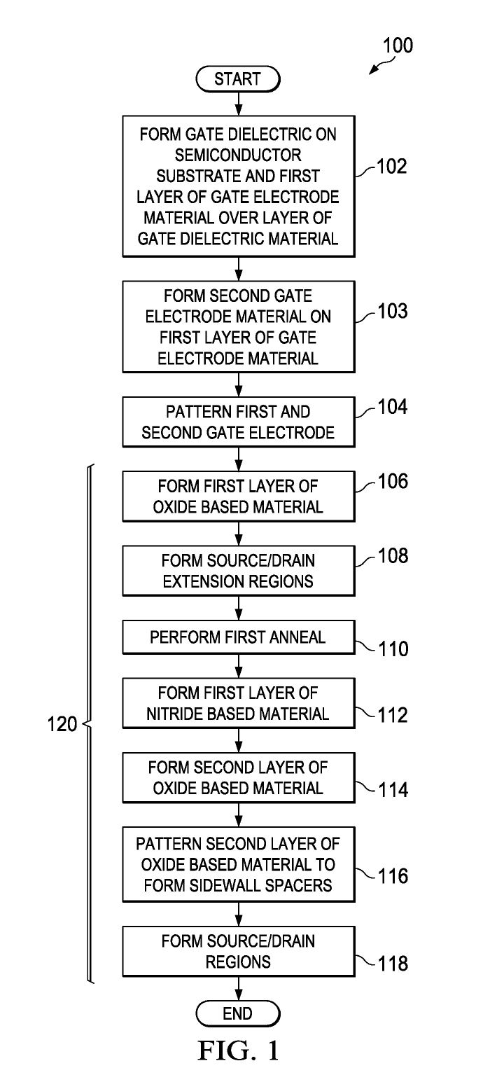

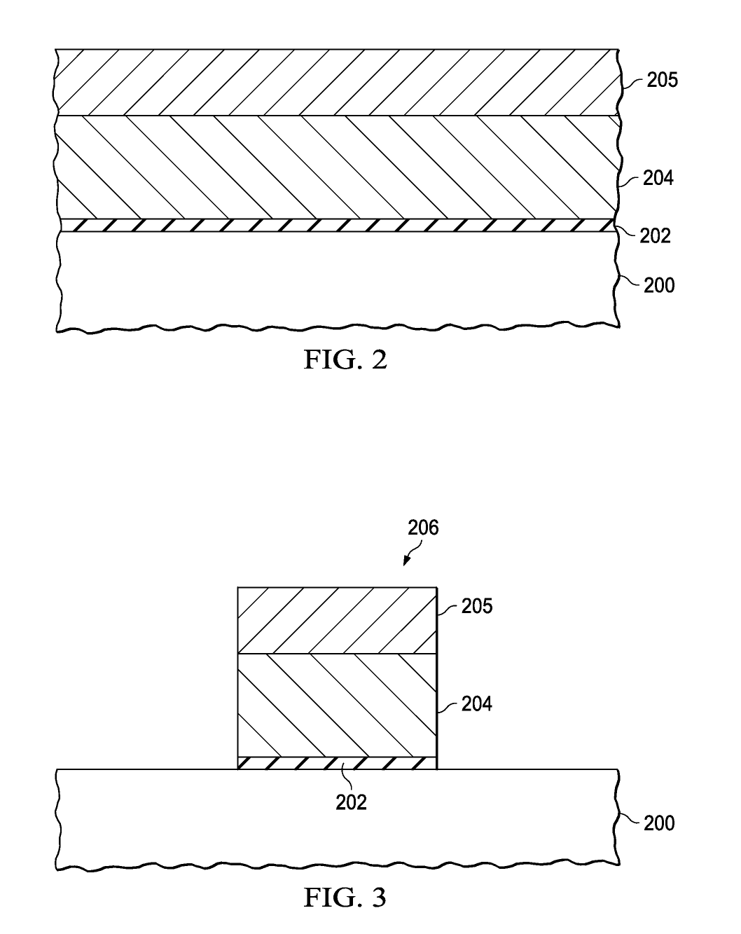

An example methodology 100 for implementing a stacked poly structure scheme is illustrated in FIG. 1, and an example semiconductor substrate 200 (FIG. 2) whereon such a methodology is implemented in forming a transistor is illustrated in cross-sectional view in FIGS. 2-9. While the method 100 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 102 (FIG. 1), a layer of gate dielectric 202 (FIG. 2) is formed over the semiconductor substrate 200 and a first layer of gate electrode material 204 is formed over the layer of gate dielectric material 202. The gate dielectric 202 generally comprises an oxide (or other dielectric) based material and/or a high-k material, for example, and is relatively thin, being formed to a thickness of between about 1 nm and about 20 nm, for example. The first layer of gate electrode material 204 generally comprises a polysilicon (or other semiconductor) based material, and is formed to a thickness of between about 20 nm and about 100 nm, for example.

At 103 in FIG. 1, a second layer of gate electrode material 205 (FIG. 2) is formed on the first layer of gate electrode material 204, for example. The second layer of gate electrode material 205 can be small grain polysilicon or thin-film amorphous silicon (a-Si), for example. The inventors recognized the advantage or improvement of the second layer of gate electrode, that by forming the stacked gate in this manner, the current semiconductor electric properties could be maintained and yet the particle generation occurring during fabrication could be reduced. The inventors also recognized the advantage of forming a stacked gate structure, the polysilicon gate electrode electrical properties could be further improved (such as increased dopant activation resulting in lower poly depletion or reduced line edge roughness resulting in less transistor variability) with little or no impact to particles. The second layer of gate electrode material 205 (FIG. 2) can be about 50% to 80% the thickness of the first layer of gate electrode material 204, for example. The second gate electrode deposition can take place at a lower deposition rate, a lower temperature, a lower pressure and a lower SiN₄ flow rate than the first gate electrode deposition, for example. The second layer of gate electrode material is formed so that the grain size distribution is smaller than the first gate electrode grain size distribution. In other words, the mean or average grain size of the second layer of gate electrode material is smaller than the mean or average grain size of the first layer of gate electrode material and the first gate and second gate layers may or may not have a different grain size standard deviation.

The first and second layers of gate electrode materials, 204 and 205 respectively, are then patterned at 104 (FIG. 1) to establish a gate structure or stack 206 (FIG. 3). It will be appreciated that this, as well as other patterning described herein, can be performed with lithographic techniques, where lithography refers to processes for transferring one or more patterns between various media. In lithography, a light sensitive resist coating is formed over one or more layers to which a pattern is to be transferred. The resist coating is then patterned by exposing it to one or more types of radiation or light which (selectively) passes through an intervening lithography mask containing the pattern. The light causes exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated (e.g., etched).

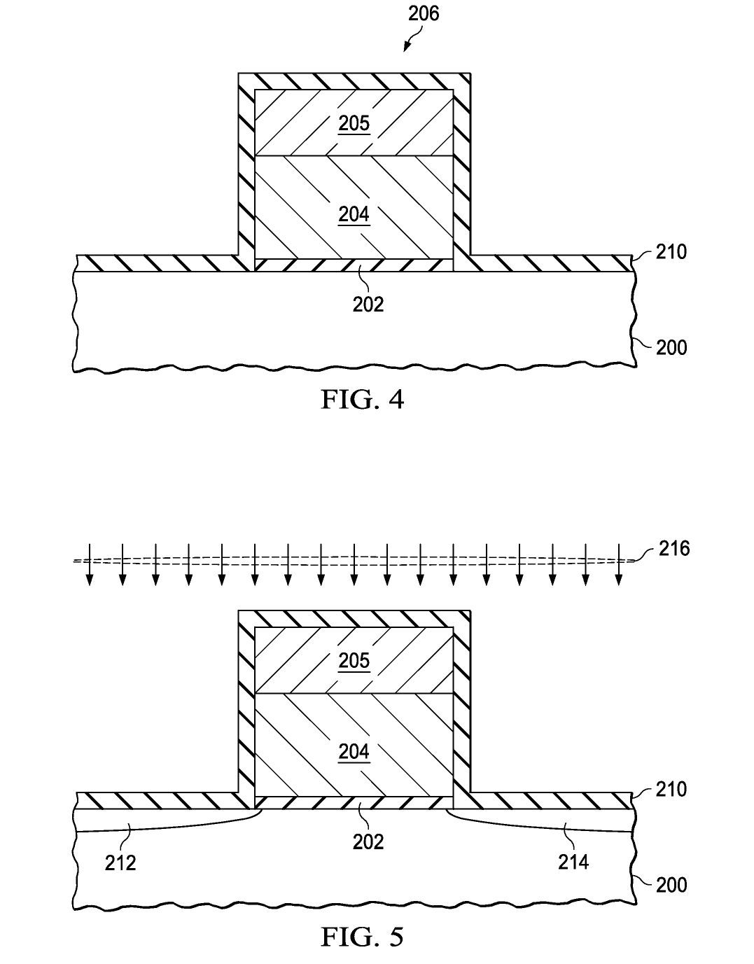

A relatively thin first layer of oxide (or other dielectric) based material 210 (FIG. 4) can then be formed over the gate stack 206 (FIG. 4) and exposed portions of the substrate 200 at 106 (FIG. 1). By way of example, the layer of oxide based material 210 may be formed by a well controlled deposition process to a thickness of between about 1 nm and about 25 nm, for example. Alternatively, a thermal growth process may be employed to form the layer of oxide based material 210. In this case, since the layer of gate electrode material 204 may comprise polysilicon, and the layer of oxide based material 210 is grown therefrom (as well as from the substrate 200), the layer of oxide based material 210 may be referred to as a layer of poly-ox based material, for example.

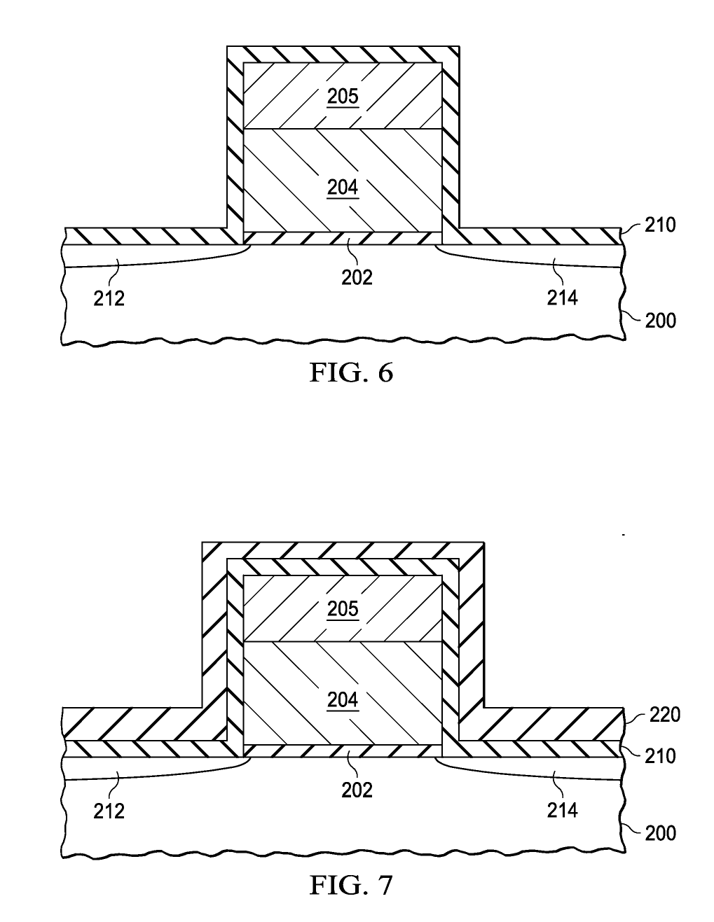

At 108 (FIG. 1), source 212 and drain 214 extension regions can be formed in the substrate 200 by a first implantation 216 (FIG. 5) whereby dopants can be implanted into the substrate 200, where the dopants can be substantially blocked by the gate stack 206 (FIG. 5). Depending upon the type of transistor being formed (e.g., PMOS or NMOS), p type dopant atoms (e.g., Boron (B)) and/or n type dopant atoms (e.g., Phosphorous (P), Arsenic (As) and/or Antimony (Sb)) can be implanted at 108 (FIG. 1). It can be appreciated that some of the dopants may also be implanted into the top of the gate electrodes 204 and 205 (FIG. 5) during the implantation at 108 (e.g., depending upon the thickness of the first layer of oxide based material 210 overlying the gate electrodes 204 and 205—which can be selectively etched a desired degree in a prior action). Similarly, the dopant atoms establishing the source 212 and drain 214 extension regions may or may not be implanted through the first 210 layer of oxide based material (or remaining degrees thereof). For example, a desired amount of areas of the first layer of oxide based 210 material overlying areas of the substrate 200 where the source 212 and drain 214 extension regions can be to be formed may be removed (e.g., etched to be thinner—or completely stripped) before the implantation 216 is performed at 108. Although not illustrated, it will be illustrated that relatively thin offset spacers may be formed along the sides of the gate stack 206 before the source 212 and drain 214 extension regions can be formed at 108. At 110, an optional first anneal is performed whereby the dopant atoms/molecules of the source 212 and drain 214 extension regions can be “activated” and driven into the gate stack 206 (FIG. 6).

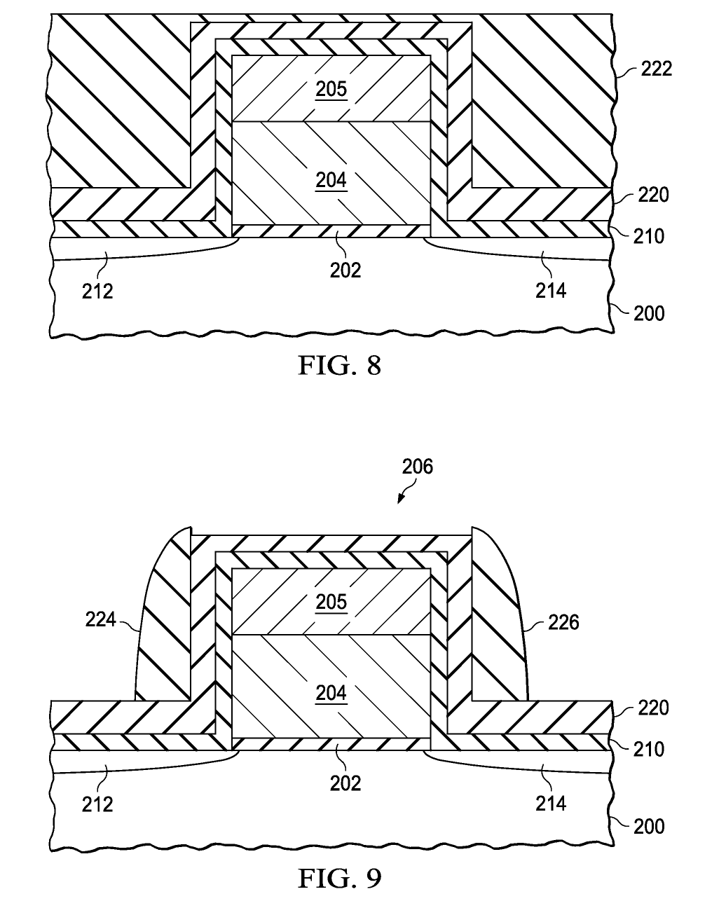

At 112 (FIG. 1), a first layer of nitride based material 220 can be formed (e.g., deposited) over the first layer of oxide based material 210 (FIG. 7). The first layer of nitride based material 220 may be formed to a thickness of between about 5 nm and about 30 nm, for example. A second layer of oxide (or other dielectric) based material 222 can be formed (e.g., deposited) over the first layer of nitride based material 220 at 114 (FIG. 8). The second layer of oxide based material 222 (FIG. 8) may be formed to a thickness of between about 10 nm and about 80 nm, for example. Although not illustrated, it will be appreciated that a thin capping oxide layer may optionally be formed over the first layer of oxide based material 210 before the nitride layer 220 is formed. The first layer of nitride based material 220 would then be formed over this capping oxide layer. Such a capping oxide layer would be processed like the oxide layer 210 (e.g., as discussed supra).

At 116 (FIG. 1), the second layer of oxide based material 222 (FIG. 8) is patterned (e.g., anisotropically etched) so that a first sidewall spacer 224 is formed on one side of the gate stack 206 and a second sidewall spacer 226 is formed on the other side of the gate stack 206 (FIG. 9). It will be appreciated that at least some of the first layer of nitride based material 220 is also removed during the patterning at 116. This can be accomplished, for example, by performing a dry etch that has a chemistry that removes the oxide based material of layer 222 substantially faster than the nitride based material of layer 220. Such chemistry may comprise oxygen and hydrogen, for example.

It will be appreciated that 106-118 (FIG. 1) represent back end processing 120 (FIG. 1). Further processing can be performed to complete the semiconductor device (e.g., creating silicide areas, annealing processes, forming metal interconnections, etc.)

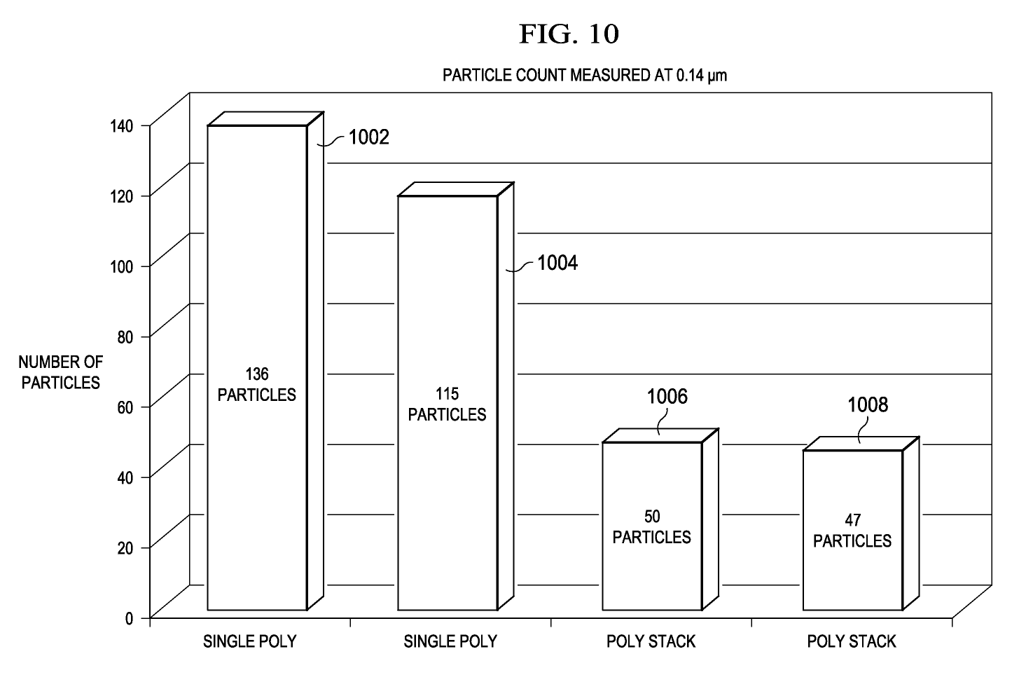

Referring now to FIG. 10, is a graph 1000 illustrating the particle count measured at 0.14 um. The graph 1000 includes two different exemplary groupings of curves 1002 and 1004 that correspond to a conventional single polysilicon gate electrode. The second groupings of curves 1006 and 1008 correspond to a polysilicon stacked gate electrode, according to the present invention. The number of particles at 0.14 um for the conventional single polysilicon gate electrodes, for example, was 136 particles (See 1002) and 115 particles (See 1004). Graph 1000 clearly illustrates that the particle count was reduced by more than 50% for the stacked gate, for example, 50 particles (See 1006) and 47 particles (See 1006)

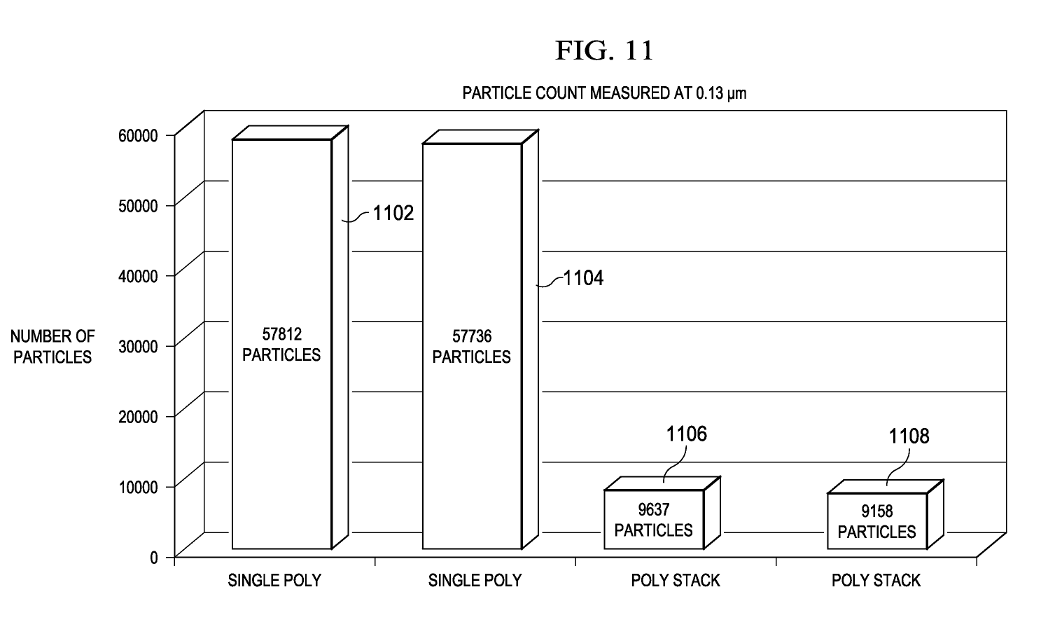

Referring to FIG. 11 in yet another test, in another embodiment of the present invention, a graph at 1100 illustrates representative particle count data that was obtained, for example, measured at 0.13 um. Curve 1100 indicates that the particle count for a stacked poly gate was reduced to below 20% of the particle count obtained with a conventional single layer polysilicon gate (1102 and 1104) to a stacked dual polysilicon gate (1106 and 1108). In this case the particle count was reduced from 57812 and 57736 particles (1102 and 1104 respectively) to 9637 and 9158 particles (1106 and 1108 respectively), clearly identifying an improvement with the present invention.

Also, equivalent alterations and/or modifications may occur to those skilled in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein

What is claimed is:

1. A method for implementing a stacked gate, comprising:
forming a gate dielectric on a semiconductor body;
forming a first layer of gate electrode material on the gate dielectric;
forming a second layer of gate electrode material on the first layer of gate electrode material;
wherein the grain size distribution of the first layer of gate electrode material is different than the grain size distribution of the second layer of gate electrode material;
implanting the first and second gate electrode materials;
patterning the first and the second gate electrodes and the gate dielectric; and
forming source and drain regions.

2. The method of claim 1, wherein the first layer of gate electrode material is polysilicon.

3. The method of claim 1, wherein the second layer of gate electrode material is polysilicon or thin-film amorphous silicon (a-Si) or both.

4. The method of claim 3, wherein the second layer of gate electrode material has a smaller grain size distribution than the first layer of gate electrode material.

5. The method of claim 1, wherein the second layer of gate electrode material comprises multiple layers of polysilicon or thin-film amorphous silicon (a-Si) or both.

6. The method of claim 3, wherein a deposition rate in forming the second layer of gate electrode is lower than a deposition rate in forming the first layer of gate electrode.

7. The method of claim 6, wherein the deposition rate in forming the second layer of gate electrode comprises at least one of the following: a lower temperature, a lower pressure and a lower SiH₄ flow rate, and a different precursor with a lower deposition rate.

8. The method of claim 7, wherein the precursor comprises at least on of the following: silane and disilane.

9. A method for reducing polysilicon particle count in a transistor, comprising;
forming a layer of gate dielectric material on a workpiece;
forming a first layer of gate electrode material on the gate dielectric material;
forming a second layer of gate electrode material on the gate dielectric material;
patterning the first and second electrode materials to form a gate structure;
forming offset spacers on the lateral edges of the gate structure;
forming source/drain extension regions;
performing a first anneal;
forming a first layer of nitride based material,
forming a second layer of oxide based material,
patterning the second layer of oxide based material to form sidewall spacers; and
forming source/drain regions.

10. The method of claim 9, wherein the first layer of gate electrode material is polysilicon.

11. The method of claim 9, wherein the second layer of gate electrode material is polysilicon or thin-film amorphous silicon (a-Si) or both.

12. The method of claim 9, wherein the second layer of gate electrode material has a smaller grain size distribution than the first layer of gate electrode material.

13. The method of claim 11, wherein the second layer of gate electrode material is multiple layers of polysilicon or thin-film amorphous silicon (a-Si) or both.

14. The method of claim 9, wherein a deposition rate in forming the second layer of gate electrode is lower than a deposition rate in forming the first layer of gate electrode.

15. The method of claim 9, wherein the SiH₄ flow rate during a deposition in forming the second layer of gate electrode material is lower than the SiH₄ flow rate during a deposition of forming the first layer of gate electrode material.

16. The method of claim 9, wherein the temperature during a deposition of forming the second layer of gate electrode material is lower than the temperature during a deposition of forming the first layer of gate electrode material.

17. The method of claim 9, wherein the pressure during a deposition of forming the second layer of gate electrode material is lower than the pressure during a deposition of the forming of the first layer of gate electrode material.

18. The method of claim 9, wherein a chamber is purged both prior to and immediately following deposition of the second layer of gate electrode material.

19. A semiconductor device formed by the process of:
(a) forming a semiconductor body;
(b) forming a gate dielectric on the semiconductor body;
(c) depositing a first gate electrode with a first grain size distribution on the gate dielectric; and
(d) depositing a second gate electrode with a second grain size distribution on the first gate electrode.

20. The device of claim 19, wherein the second gate electrode grain size distribution is smaller than a first gate electrode grain size distribution.

21. The device of claim 19, wherein first and second gate electrodes are patterned to form a gate structure, offset spacers are formed on lateral edges of the gate structure, source/drain extension regions are formed in the device, a first anneal is performed on the device, and source/drain regions are formed within the device.

22. The device of claim 19, wherein the second gate electrode deposition comprises a lower deposition rate by at least one of the following: a lower temperature, a lower pressure and a lower SiH₄ flow rate, and a different precursor with a lower deposition rate.

23. The method of claim 22, wherein the precursor comprises at least one of the following: silane and disilane.
